(19) United States
(12) Patent Application Publication
(10) Pub. No.: US 2005/0048715 A1
(43) Pub. Date: Mar. 3, 2005

(54) Trench capacitor with pillar

(76) Inventors: Thomas Steffen Rupp, Faak am See (AT); Stephan Kudelka, Ottendorf-Okrilla (DE); Alexander Michaelis, Langelsheim (DE); Carl J. Radens, Lagrangeville, NY (US)

Correspondence Address: SLATER & MATSIL, L.L.P., 17950 PRESTON RD, SUITE 1000, DALLAS, TX, 75252-5793, US

(21) Appl. No.: 10/651,392

(22) Filed: Aug. 29, 2003

(51) Int. Cl. H01L 21/8234; H01L 21/8244

(52) U.S. Cl. 438/244; 438/387

(57) ABSTRACT

A trench capacitor having a conductive pillar in a central region of a trench. A first plate of the capacitor includes the substrate in the lower portion of the trench and the conductive pillar. The capacitor dielectric is disposed over the conductive pillar and the sidewalls of the trench lower portion. A second plate of the capacitor is a conductive material disposed over the dielectric material. The conductive pillar increases the surface area of the capacitor plates, increasing the capacitance of the capacitor. A top portion of the conductive pillar may be hollow, further increasing the surface area of the capacitor plates.

### TECHNICAL FIELD

The present invention relates generally to the fabrication of semiconductor devices, and more particularly to the fabrication of capacitors.

### BACKGROUND

Semiconductor devices are used in a variety of electronic applications, such as personal computers and cellular phones, for example. One such semiconductor product widely used in electronic systems for storing data is a semiconductor memory device, and a common type of semiconductor memory is a dynamic random access memory (DRAM).

A DRAM typically includes millions or billions of individual DRAM cells arranged in an array, with each cell adapted to store one bit of data. A DRAM memory cell typically includes an access field effect transistor (FET) and a storage capacitor. The access FET allows the transfer of data charges to and from the storage capacitor during reading and writing operations. In addition, the data charges on the storage capacitor are periodically refreshed during a refresh operation.

DRAM storage capacitors are typically formed by etching trenches in a semiconductor substrate, and depositing, patterning and doping a plurality of layers of conductive, semiconductive and insulating materials in order to produce storage capacitors that are adapted to store data, which is represented by a one or zero. Prior art planar DRAM designs typically comprise an access transistor 122 disposed in a subsequently deposited layer, disposed above and to the side of the storage capacitors 110 which are formed in trenches 104, as shown in FIG. 1.

The semiconductor industry in general is being driven to decrease the size and increase the number of semiconductor devices on integrated circuits. Miniaturization is generally needed to accommodate the increasing density of circuits necessary for today's semiconductor products. A more recent DRAM design involves disposing the access FET directly above the storage capacitor, a design that is often referred to as a vertical DRAM, which saves space and results in the ability to place more DRAM cells on a single chip.

In both planar and vertical memory devices such as DRAM's, a capacitance of about 20 to 40 fF is typically required for the capacitors formed in the trenches. However, as ground rules are scaled or reduced, it becomes more and more difficult to manufacture trench capacitors having the capacitance required for the circuit requirements. For example, the trenches generally have high aspect ratios, which are more difficult to process, and the lateral surface area of the chip surface area needs to be conserved. Therefore, what is needed in the art is a method and structure for a capacitor that meets the reduced ground rule requirements yet provides the required capacitance.

### SUMMARY OF THE INVENTION

These and other problems are generally solved or circumvented, and technical advantages are generally achieved, by preferred embodiments of the present invention, which provide a capacitor having an increased surface area of the plates. A pillar is formed in the center of the trench that is electrically connected to the buried plate or outer capacitor plate in the bottom of the trench. Thus, the surface area of the capacitor plates is increased, providing increased capacitance without increasing the depth or width of the trench.

In accordance with a preferred embodiment of the present invention, a semiconductor device includes a substrate, at least one trench formed in the substrate, the trench having a bottom surface and sidewalls, the trench comprising a lower portion, and a conductive pillar formed in the trench lower portion, the pillar being disposed over and electrically connected to the bottom surface of the trench. A dielectric material is disposed over the pillar and the sidewalls of the trench lower portion, and a first conductive material is disposed over the dielectric material. The substrate in the lower portion of the trench and the conductive pillar comprise a first plate of a capacitor, the dielectric material comprises a dielectric of the capacitor, and the first conductive material comprises a second plate of the capacitor.

In accordance with another preferred embodiment of the present invention, a capacitor includes a substrate and at least one trench formed in the substrate, the trench having a bottom surface and sidewalls, the trench comprising a lower portion. A conductive pillar is formed in the trench lower portion, the pillar being disposed over and electrically connected to the bottom surface of the trench, wherein the substrate in the lower portion of the trench and the conductive pillar comprise a first plate of the capacitor. A capacitor dielectric is disposed over the pillar and the sidewalls of the trench lower portion. A conductive material is disposed over the dielectric material, the conductive material being recessed below a top surface of the pillar, wherein the conductive material comprises a second plate of the capacitor.

In accordance with yet another preferred embodiment of the present invention, a method of manufacturing a semiconductor device includes providing a substrate, and forming at least one trench in the substrate. The at least one trench includes a bottom surface, sidewalls, a lower portion and an upper portion. The method includes forming a conductive pillar in the trench lower portion, wherein the pillar is electrically connected to the bottom surface of the trench. A dielectric is deposited over the pillar and trench sidewalls, and a first conductive material is deposited over the dielectric.

Advantages of preferred embodiments of the present invention include increasing the surface area of capacitor plates, thus increasing the capacitance. The capacitance of a trench capacitor can be doubled, resulting in the ability to manufacture shallower, narrower trenches without sacrificing capacitance. Manufacturing a trench capacitor having a pillar inside the trench as described herein results in the ability to reduce the ground rules or place more trenches into the same unit area. In one embodiment, the conductive pillar is hollow, further increasing the surface area of the capacitor plates and thus further increasing, e.g., almost tripling, the capacitance. Embodiments of the present invention are particularly advantageous in scaled-down memory devices having ground rules of less than about 0.15 μm, for example.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a prior art planar DRAM device having a trench storage capacitor and a lateral access transistor;

FIGS. 2 through 11 show cross-sectional views of a capacitor having a conductive pillar in the central region thereof in accordance with a preferred embodiment of the present invention at various stages of manufacturing;

FIGS. 12 to 15 show cross-sectional views of another embodiment of the present invention, wherein the conductive pillar has a hollow top portion;

FIG. 16 illustrates the conductive pillar described herein used in a memory device having a lateral access transistor; and

FIG. 17 illustrates a hollow conductive pillar described herein used in a memory device having a vertical access transistor.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a DRAM device. The invention may also be applied, however, to other memory devices and semiconductor applications requiring or utilizing trench capacitors. A cross-sectional view of one capacitor is shown in each figure, although many other capacitors and components may be present in the semiconductor devices shown.

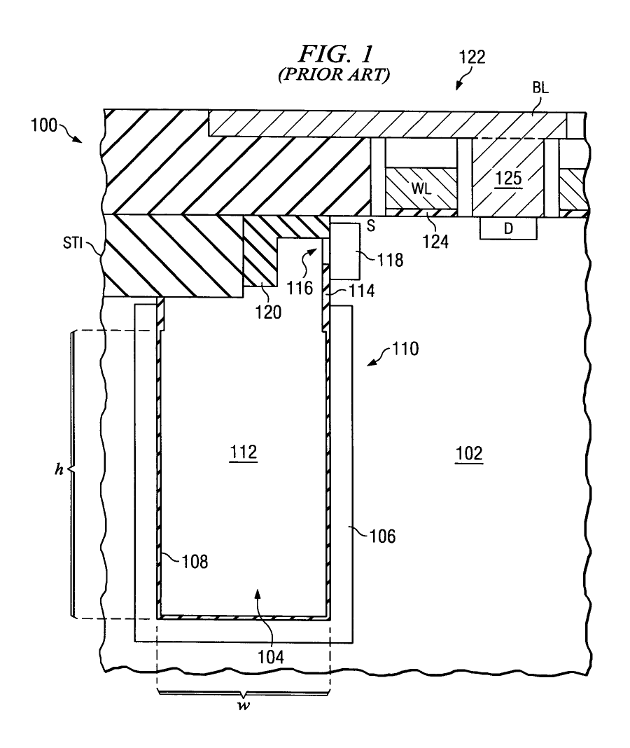

With reference now to FIG. 1, a prior art trench DRAM device 100 having a lateral access device 122 is shown. A trench 104 is formed in a substrate 102. A top portion of the trench 104 may be oxidized using a locally oxidized (LOCOS) collar 114 process or other process, and a buried plate 106 is formed by doping the sidewalls and bottom portion of the trench 104. A thin capacitor dielectric 108 is formed over the buried plate 106, and polysilicon 112 is deposited in the trench 104 to form the storage trench capacitor 110. A buried strap 116 is formed over the capacitor 110 proximate a buried strap outdiffusion region 118 in the substrate, and a trench top oxide (TTO) 120 is formed over the buried strap 116. The lateral access device 120 comprises a source S proximate the buried strap outdiffusion region 118, a drain D and a gate formed by a wordline WL disposed over a gate oxide 124. The drain D is connected to the bitline BL by a bitline contact 125. Each trench storage capacitor is located proximate the intersection of a wordline WL and bitline BL in the memory array, and is accessed, e.g., read or written to, by selecting the wordline WL and bitline BL for that particular memory cell.

The capacitance C of a trench capacitor such as the one shown at 110 is determined by the following equation:

$$\begin{matrix}\text{Eq. 1:} \\ C = \frac{ɛ A}{d}\end{matrix}$$

where ε is the dielectric constant of the capacitor dielectric 108 between the capacitor plates, A is the surface area of the capacitor dielectric 108 between the capacitor plates 106 and 112, and d is the thickness of the dielectric material 108 between the plates 106 and 112. The area A is a function of the height h and the perimeter of the capacitor dielectric 108 between the plates 106 and 112, represented in a two-dimensional form as the width w. The trench 104 is shown in a cross-sectional view in FIG. 1; however, the trench 104 may actually be round, elliptical, square, rectangular or other three-dimensional shapes, for example. The greater the area A, the greater the capacitance C of the capacitor 110. Note that the bottom capacitor plate 106 and the top plate 112 have a slightly increased surface area, compared to the dielectric 108. The excess surface area of plate 106 proximate the collar oxide 114 does not significantly contribute to the capacitance of the capacitor.

To maximize capacitance while minimizing the use of lateral surface area, recent DRAM designs have seen decreasing widths w and increasing heights h for trench capacitors. However, there are challenges in processing high aspect ratio structures, which may be 10:1 (height to width ratio) or greater, particularly at ground rules of 150 nm or less, for example. Also, reducing the lateral chip dimensions results in a reduction of active capacitor area.

Furthermore, the dielectric often used as a dielectric in trench capacitors is oxinitride, which has a dielectric constant ε of about 7. The smallest possible thickness d of this dielectric material is about 1 to 2 nm, which is another limiting factor in scaling or reducing the size of trench capacitors.

Embodiments of the present invention provide a method of manufacturing a trench capacitor in which capacitance is increased without requiring a greater height and/or wider width of a trench in order to achieve the capacitance increase. A conductive pillar is formed at the bottom of each trench abutting the buried plate of the trench capacitor. The surface area of the capacitor plates is increased by the amount of the surface area of the pillar, resulting in an increase in the capacitance.

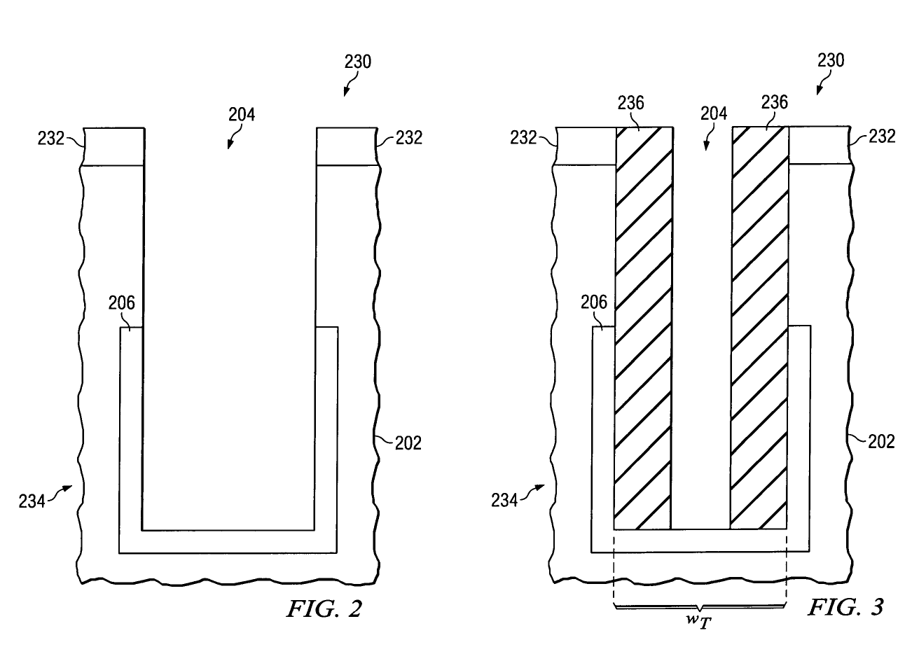

FIGS. 2 through 11 illustrate cross-sectional views of a trench capacitor 230 at various stages of manufacturing in accordance with a preferred embodiment of the present invention. A substrate 202 is provided, as shown in FIG. 2. The substrate 202 typically comprises a semiconductor material such as single-crystal silicon. The substrate 202 may also comprise a workpiece including other conductive layers or other semiconductor elements such as transistors or diodes disposed therein, as examples. The substrate 202 may alternatively comprise other semiconductors such as GaAs, InP, Si/Ge, SiC, or compound semiconductors, as examples. The substrate 202 and various layers formed thereon are also referred to herein collectively as a wafer.

A pad oxide comprising a thickness of 1-5 nm, for example, is deposited over the substrate 202, not shown. A pad nitride 232 is deposited over the pad oxide. The pad nitride 232 may comprise silicon nitride deposited in a thickness of 100 to 300 nm, for example, and alternatively, the pad nitride 232 may comprise other nitride materials. An optional oxide hard mask may be deposited over the pad nitride 232, not shown. The optional oxide hard mask may be used to etch the trenches 204, and may then be removed, leaving the pad nitride 232 at the top surface.

The wafer is patterned using conventional lithography techniques and etched to form trenches 204 in the substrate 202 and pad nitride 232, as shown. The trenches 204 may be 8 μm deep and 150 μm or less in width, as examples, although these parameters are a function of the ground rules for the particular device being manufactured and may comprise other depths and widths, for example. The trenches 204 are preferably typically substantially oval or rectangular, comprising one unit of minimum feature size in width on one side and two units of minimum feature size in width on the other side, for example. Alternatively, the trenches 204 may comprise other three-dimensional shapes, for example.

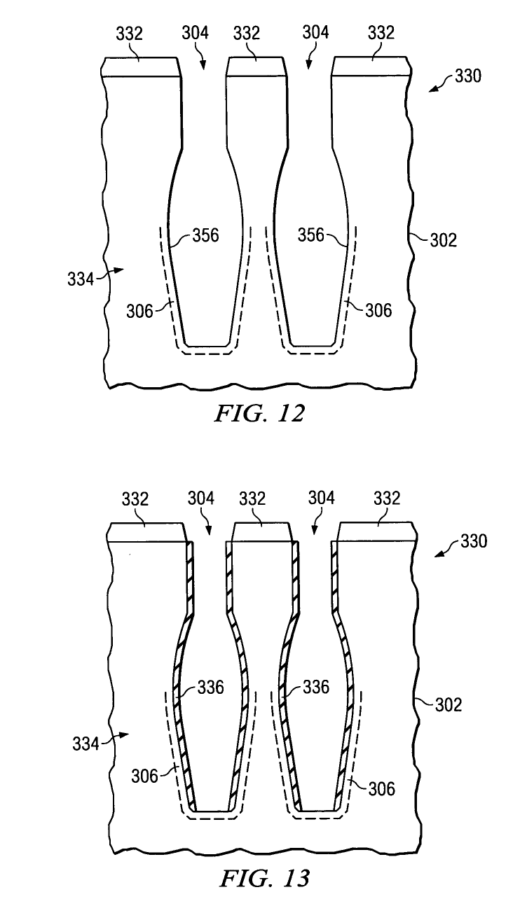

The trench sidewalls and bottom surface may optionally be bottle-etched (not shown in FIG. 2: see FIG. 12.) The trench sidewalls and bottom surface are doped, e.g., with n type doping or other type of doping, to form a buried plate 206 in the lower portion 234 of the trench 204, as shown in FIG. 2.

A disposable oxide 236 is deposited over the sidewalls and bottom of the trench 204, as shown in FIG. 3. The oxide 236 may comprise silicon dioxide deposited by chemical vapor deposition (CVD) in a thickness ¼ to ⅓ of the width WT of the trench, for example. The oxide 236 may comprise a thickness of about 30 nm for 100 nm ground rules, as an example. The oxide 236 is removed from the bottom of the trench 204, using an anisotropic etch process, for example, exposing a central portion of the bottom of the trench 204. The etch process may comprise an anisotropic oxide reactive ion etch (RIE), as an example.

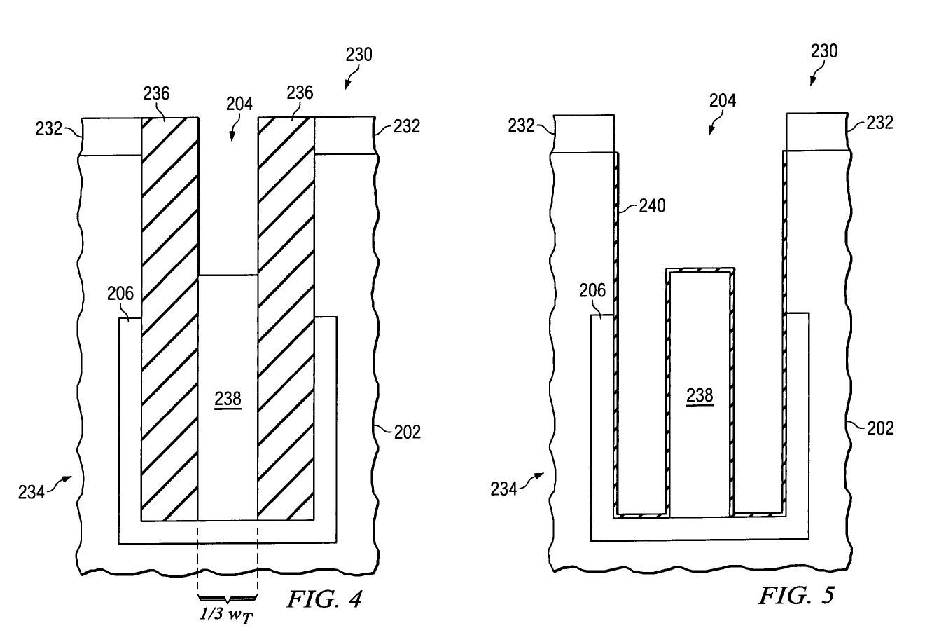

A conductive material is deposited over the wafer to fill the trench 204. The conductive material is then recessed to a predetermined height below the top surface of the substrate 202 to form a conductive pillar 238, as shown in FIG. 4. The conductive material preferably comprises polysilicon and may alternatively comprise other semiconductive materials, as example. The conductive material 238 comprises n type polysilicon that is deposited using an in situ deposition method in one embodiment, for example. The conductive material may be recessed by chemically-mechanically polishing the surface of the wafer to remove the excess conductive material from the top surface of the pad nitride 232, followed by a timed etch to recess the conductive material below the substrate 202 top surface. Alternatively, an endpoint etch may be used to detect when the conductive material is removed from the top surface of the pad nitride 232, for example. The amount of recess below the pad nitride 232 top surface may be about 300 to 1300 nm for a device having a vertical access device, for example, and the amount of recess below the pad nitride 232 top surface may be about 200 to 800 nm for a device having a lateral access device, for example. The depth of the recess depends upon the ground rules, dimensions of the trench, and the amount of capacitance desired, as examples.

The disposable oxide 236 is removed, using an etch selective to nitride and polysilicon, for example, as shown in FIG. 5. The oxide 236 etch may comprise a wet HF etch chemistry or a dry RIE process, for example.

A dielectric material 240 is deposited over the trench sidewalls, exposed portions of the trench bottom surface, the pillar sidewalls, and the pillar top surface, as shown also in FIG. 5. The dielectric material 240 functions as the node dielectric or capacitor dielectric of the trench capacitor. The dielectric material 240 preferably comprises nitrided oxide or a trilayer of nitride/oxide/nitride, as examples. To form the nitrided oxide, for example, an oxide layer may be deposited, and a nitride may be grown over the oxide. The dielectric material 240 may alternatively comprise other dielectric materials suitable for a capacitor dielectric. The dielectric material 240 preferably comprises a thickness of 10 nm or less, and more preferably comprises a thickness of 1 to 2 nm, as examples.

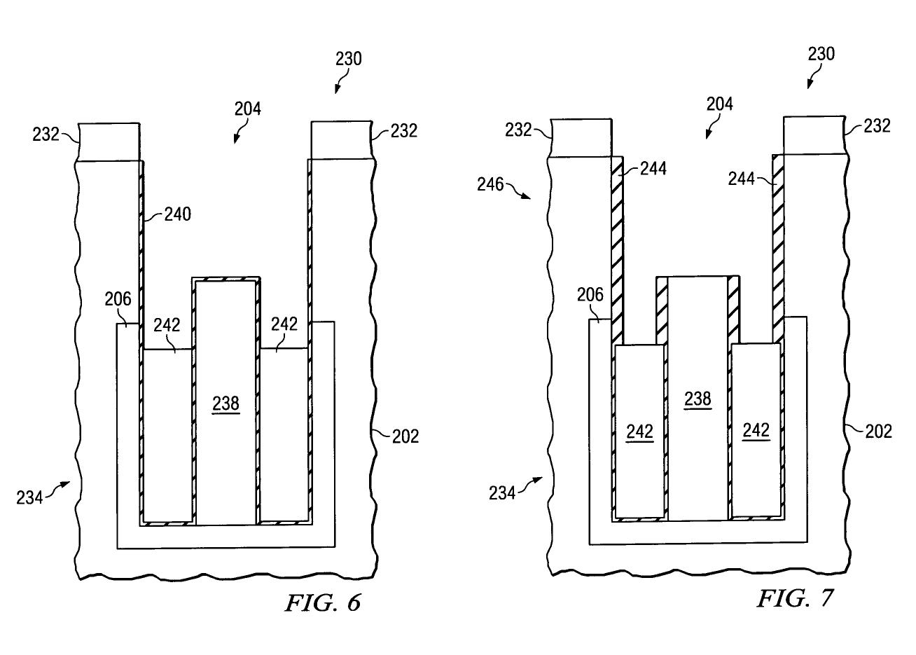

A conductive material is deposited over the wafer to fill the trench 204. The conductive material is then recessed to a predetermined height below the top surface of the pad nitride 232 to form a capacitor top plate 242 over the dielectric material 240, as shown in FIG. 6. The conductive material 242 preferably comprises polysilicon and may alternatively comprise other semiconductive materials, as example. The conductive material preferably comprises n type polysilicon that is deposited using an in situ deposition method in one embodiment, for example. The conductive material may be recessed by chemically-mechanically polishing the surface of the wafer to remove the excess conductive material from the top surface of the pad nitride 232, followed by a timed etch to recess the conductive material below the substrate 202 top surface. Alternatively, an endpoint etch may be used to detect when the conductive material is removed from the top surface of the pad nitride 232, for example. The amount of recess below the pad nitride 232 top surface defines the lower edge of the collar, and may be about 600 to 2300 nm for a device having a vertical access device, for example. The amount of recess below the pad nitride 232 top surface may be about 500 to 1800 nm for a device having a lateral access device, for example. The amount of recess may vary due to the consumption of a portion of the pad nitride 232 during the various etch processes described herein.

Also, the top plate 242 conductive material is preferably recessed below the top surface of the conductive pillar 238. For example, the top plate 242 conductive material may be recessed between about 300 to 1000 nm below the top surface of the conductive pillar 238, in one embodiment.

An insulating collar 244 is deposited in the upper portion 246 of the trench 204, as shown in FIG. 7. The insulating collar 244 preferably comprises an oxide, and may comprise silicon dioxide deposited by locally grown silicon oxide, or by CVD oxide, as examples, although other insulators may be used. The insulating collar 244 is preferably conformal (not shown: FIG. 7 shows the structure after an anisotropic etch of the insulating collar 244 material) to the exposed surfaces of the pad nitride 232, trench 204 sidewalls, pillar 238 sidewalls and top surface, and top surface of the top plate material 242, for example. The insulating collar 244 material may comprise a thickness of about 5 to 20 nm, as an example.

The insulating collar 244 material is etched to open the top of the capacitor top plate 242 and the top of the conductive pillar 238, as shown in FIG. 7, preferably using an anisotropic etch which preferentially removes the insulating collar 244 material from the top surface of the top plate 242 and the top surface of the conductive pillar 238, while leaving the insulating collar 244 material residing over the sidewalls of the trench 204 and pillar 238.

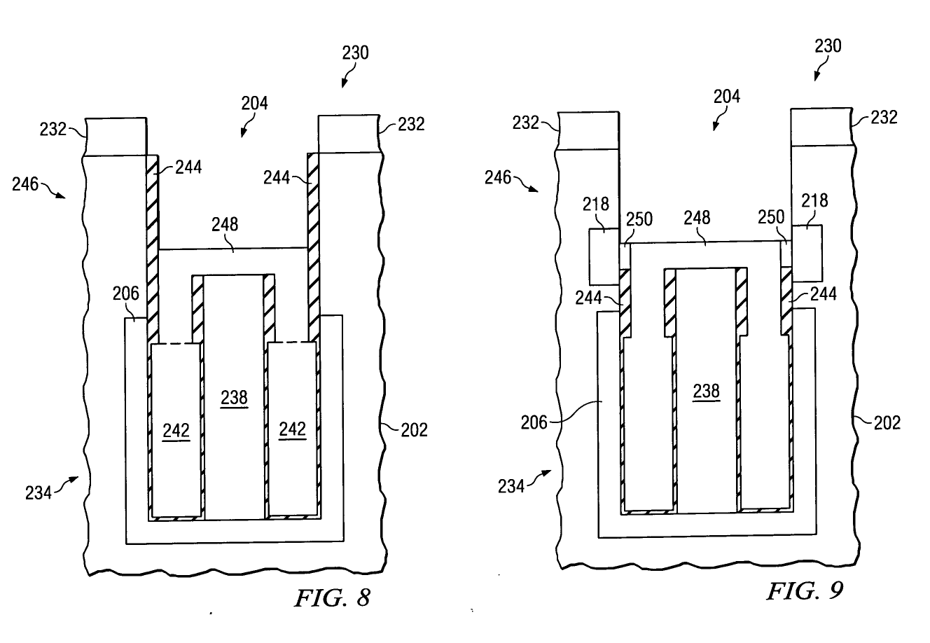

A conductive material 248 is deposited over the wafer to fill the trench 204. The conductive material 248 is then recessed to a predetermined height below the top surface of the pad nitride 232, as shown in FIG. 8. The conductive material 248 preferably comprises polysilicon and may alternatively comprise other semiconductive materials, as example. The conductive material 248 comprises highly doped n type polysilicon that is deposited using an in situ deposition method in one embodiment, for example. The amount of recess below the pad nitride 232 top surface may be about 250 to 1100 nm for a device having a vertical access device, for example. The amount of recess below the pad nitride 232 top surface may be about 150 to 600 nm for a device having a lateral access device, for example.

Processing is continued to complete the manufacturing of the trench capacitor 230 memory cell. The exposed insulating collar 244 is removed, including a small portion of the insulating collar 244 proximate the top surface of the conductive material 248, leaving a divot. The divot is filled with conductive material 250 to form a buried strap 250, as shown in FIG. 9. The conductive material 250 preferably comprises undoped polysilicon, for example. Angled implantation may be used to form a buried strap outdiffusion region 218 in the upper part of the trench. Alternatively, the buried strap outdiffusion region 218 may be formed by outdiffusion of dopants from the doped polysilicon 248 or both the doped polysilicon 248 and buried strap 250, for example.

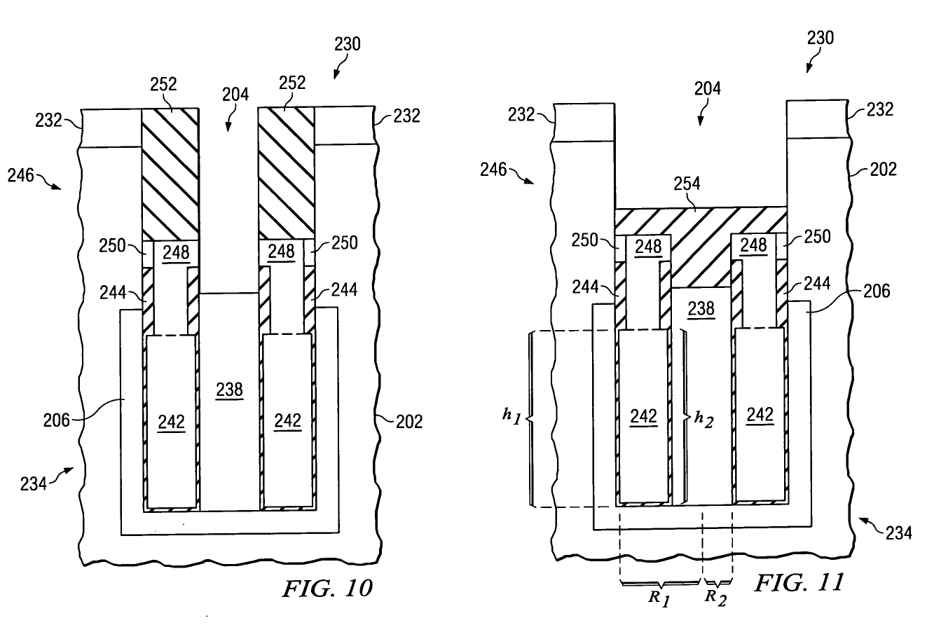

An insulating layer 252 comprising silicon dioxide, for example, is deposited using CVD over the wafer to conformally coat the trench sidewalls, top surface of the pad nitride 232, and top surface of the conductive material 248 in the trench 204 (again, FIG. 10 shows the structure after the anisotropic etch). The insulating layer 252 is removed from the top surface of the conductive material 248 over the pillar 238 and from over the pad nitride 232, using an anisotropic oxide RIE process adapted to stop on polysilicon, for example, although alternatively, other etch processes may be used. The pillar 238 is preferably over-etched by about 100 to 1000 nm in order to isolate the pillar 238 from the conductive material 248. Preferably, the pillar 238 is recessed below the buried strap by about 50 to 150 nm to ensure that the top surface of the pillar 238 is below the top of the collar 244.

The insulating layer 252 is removed, and a trench top oxide 254 (TTO) is formed over the buried strap 248 and 250 and pillar 238, as shown in FIG. 11. To form the TTO 254, an insulating material such as an oxide is deposited to fill the trench 204 and then recessed to a height of about 100 to 500 nm from the top surface of the substrate 202 for a vertical device, for example.

The trench capacitor 230 comprises a bottom plate, which is formed by the lower portion of the trench 204 sidewalls and the trench 204 bottom surfaces not abutting the pillar 238 (both comprising portions of the buried plate 206) and the pillar 238 sidewalls; a capacitor dielectric 240; and a top plate formed by conductive material 242. The trench capacitor 230 has an increased capacitance due to the increased surface area of the plates 206/238 and 242. For example, the bottom plate 206/238 and top plate 242 surface areas comprise a height h₁ along the sidewall of the trench 204 and a height h₂ along the sidewalls of the pillar 238, where h₁ is substantially equal to h₂. The radius of the trench 204 is R₁, and the radius of the pillar 238 is R₂, in the case of a circular trench, for example. The capacitor plate surface area is a function (e.g., perimeter×height) of the perimeter and the height h₁ and h₂, wherein the perimeter is equal to 2πR₁ for the trench 204 and 2πR₂ for the pillar 238. Embodiments of the present invention increase the surface area of the dielectric 240 and capacitor plates 206/238 and 242 with the additional surface area provided by the pillar 238.

Note that the lateral dimensions, e.g., the radiuses R₁ and R₂, are substantially smaller than the depth of the trench 204, and thus, the bottom of the trench 204 is not a large contributing factor to the capacitance of the capacitor 230. Therefore, while the amount of surface area of the buried plate 206 in the bottom of the trench 204 is decreased by the portion of the pillar 238 disposed along the bottom of the trench, the additional surface area provided by the pillar 238 sidewalls is a significantly larger surface area and thus creates an increased capacitance for the capacitor 230.

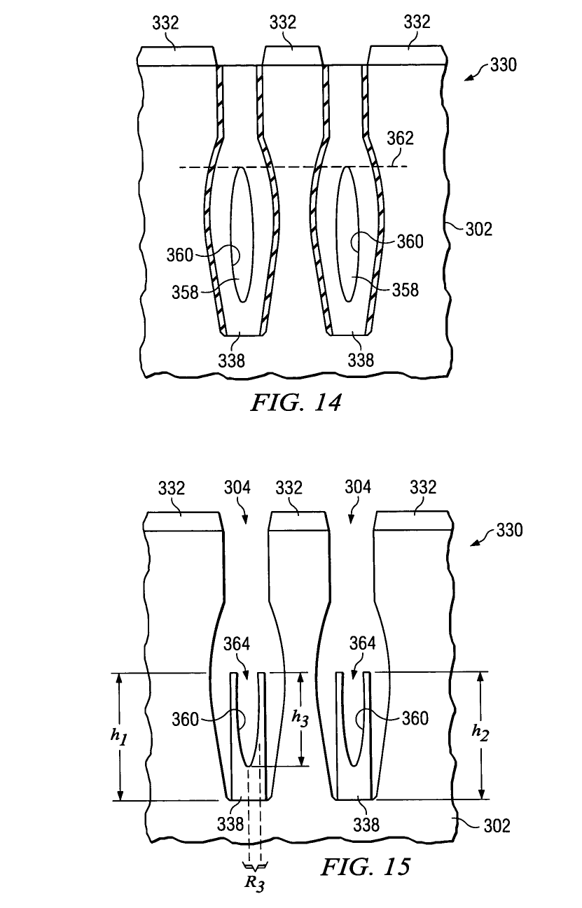

Another preferred embodiment of the present invention is shown in FIGS. 12 through 15. A process flow similar to the one described for FIGS. 2 through 11 may be used to manufacture the trench capacitor 330. However, in this embodiment, the trenches 304 are preferably widened at the lower portion 334 using a bottle etch 356, as shown in FIG. 12. The substrate 302 and pad nitride 332 are etched, with trenches 304 having a bottle shape, and the trench 304 bottom and sidewall surfaces in the lower portion 334 are doped to form a buried plate 306. The trenches 304 may comprise a depth of 5 μm and a width of less than 250 nm, for example. A LOCOS process may be used to form about 35 nm of an oxide 336 such as silicon dioxide on the vertical trench surface, as shown in FIG. 13. The silicon dioxide 336 is removed from the trench 304 bottom surface by an anisotropic RIE process, for example. A conductive material 338 is deposited into the trenches 304, as shown in FIG. 14. As in the previous embodiment described, preferably, the conductive material 338 comprises polysilicon that is highly n doped. The conductive material 338 is recessed to form a pillar 338, as shown in FIG. 15.

In this embodiment, because of the bottle-shape of the trench lower portion and the material properties of the conductive material 338 deposited, a void 358 is formed in the lower part of the trench in the pillar, as shown in FIG. 14. The formation of the void 358 is advantageous in that a pillar may be formed that has a hollow portion 364 at the top, to be described further herein.

The void 358 comprises an inner surface 360. The wafer surface is planarized using CMP, and the conductive material 338 is recessed using a RIE process, for example, to a depth of about 1.5 μm, as an example. The etch process for recessing of the conductive material 338 may comprise an isotropic etch until the void 358 is reached, for example at 362, at which time the etch process is changed to an anisotropic etch to preferentially etch the conductive material 338 in a vertical direction within the trench 304.

An optional thin liner (not shown) may be formed over at least the inner surface 360 of the void 358 after the isotropic etch to remove the top portion of the conductive material 338, which opens the void 358. The thin liner protects the inner surface 360 of the hollow portion 364 of the pillar 338 during the subsequent anisotropic etch process. The thin liner may comprise 1 to 3 nm of an oxide. The thin liner may alternatively comprise 1 to 3 nm of a polymer, which may be formed as a byproduct during the isotropic and/or anisotropic etch process. The polymer passivates the sidewalls of the hollow pillar 338 while the conductive material 338 is removed between the pillar outer sidewalls and the bottle-shaped trench 304. Alternatively, the thin liner may comprise other materials, for example. The optional thin liner, when used, is removed before depositing the capacitor dielectric (not shown in FIG. 14 or 15: see 240 in FIG. 5), for example, using a wet cleaning process, although other methods may also be used to remove the thin liner.

The resulting structure is shown in FIG. 15, wherein a top portion of the pillar 338 comprises a hollow portion 364. The hollow portion 364 is defined by the inner surface 360 of the void 358. Advantageously, additional surface area is created by the hollow portion 364 of the pillar 338. The hollow portion 364 has a height h₃, for example. Therefore, in this embodiment, the surface area for the capacitor plates are a function not only of height h₁ and perimeter of the trench 304 sidewalls and the height h₂ and perimeter of the pillar 338 sidewalls, but also in addition, the capacitor plate surface area is increased as a function of the height h₃ and perimeter of the hollow portion 364 of the pillar 338 (wherein the hollow portion 364 perimeter is 2πR₃, wherein R₃ is the radius of the hollow portion 364, for a circular hollow portion 364), further increasing the capacitance of the trench capacitor 330.

The LOCOS oxide 336 is removed, for example, using a wet HF chemistry, and the trench capacitor is processed according to the method described with reference to the embodiment shown in FIGS. 5 through 11, for example.

Preferably, a bottle etch shaped trench is used to form the hollow pillar 338 in accordance with an embodiment of the present invention, because of the ease of generating the void 358. However, the hollow pillar 338 may also be formed in a vertical, e.g., non-bottle etch shaped trench, by proper selection of materials and etch processes.

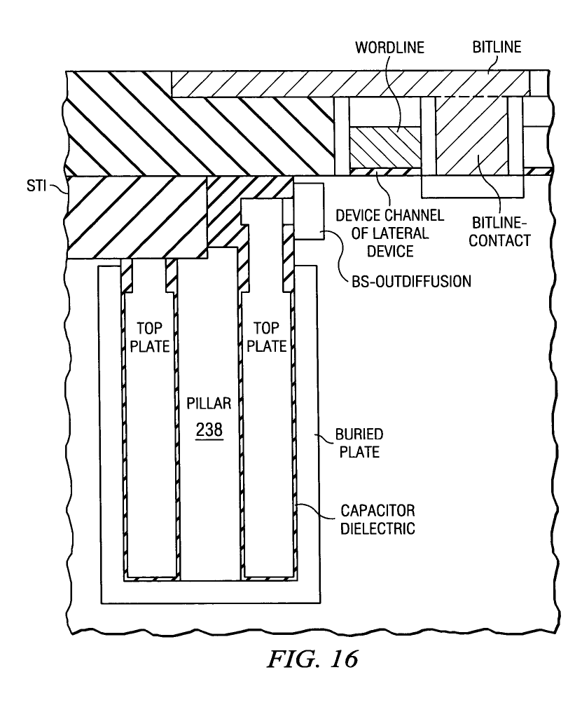

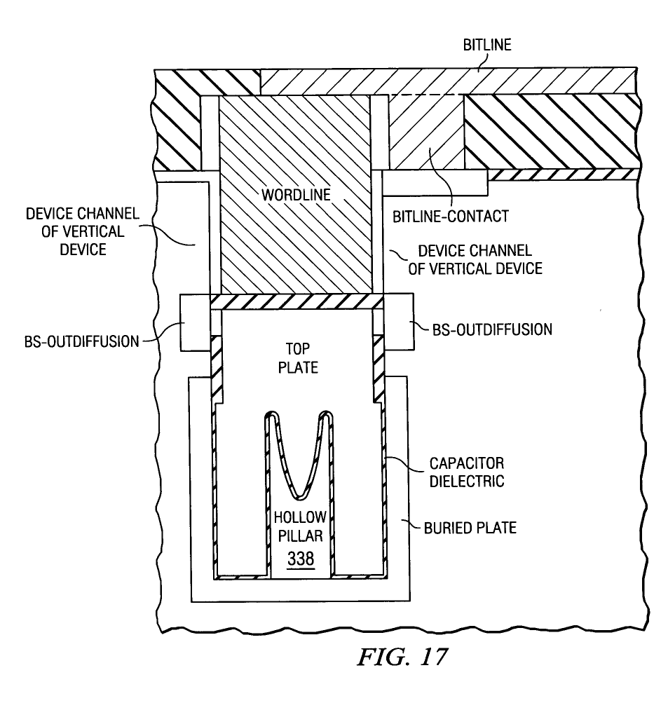

FIG. 16 shows a conductive pillar 238 in accordance with an embodiment of the present invention implemented in a lateral access array device. FIG. 17 shows a conductive pillar 338 described herein having a hollow portion 364 implemented in a vertical access array device. Conversely, conductive pillar 238 may be implemented in a vertical access array device, and hollow conductive pillar 338 may be implemented in a lateral access array device, not shown.

Advantages of embodiments of the invention include providing a trench capacitor having a higher capacitance for a given depth and width. The capacitance of a trench capacitor 230/330 may be doubled or tripled by increasing the surface area of the plates, by forming the conductive pillar 238/338 electrically coupled to the bottom plate 206/306, as described herein. This allows the use of smaller structures, e.g., trenches 204/304, and provides the ability to manufacture more memory cells per square unit of surface area. Furthermore, the depth of the trenches 204/304 may be reduced, making the processing of the trench capacitors 230/330 more reliable, easier, and less costly. Embodiments of the present invention are particularly useful in ground rules of 150 nm or less, for example.

While embodiments of the present invention are primarily described herein with reference to DRAM devices, they also may have useful application in ferroelectric random access memory (FRAM) devices and other semiconductor devices that implement trench capacitors, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device, comprising:
a substrate;
at least one trench formed in the substrate, the at least one trench having a bottom surface and sidewalls, the at least one trench comprising a lower portion;
a conductive pillar formed in the trench lower portion, the pillar being disposed over and electrically connected to the bottom surface of the at least one trench;
a dielectric material disposed over the pillar and the sidewalls of the trench lower portion; and
a first conductive material disposed over the dielectric material, wherein the substrate in the lower portion of the at least one trench and the conductive pillar comprise a first plate of a capacitor, the dielectric material comprises a dielectric of the capacitor, and the first conductive material comprises a second plate of the capacitor.

2. The semiconductor device according to claim 1, wherein at least a top portion of the conductive pillar is hollow.

3. The semiconductor device according to claim 2, wherein the at least one trench comprises a bottle shape at the lower portion.

4. The semiconductor device according to claim 1, wherein the first conductive material comprises polysilicon.

5. The semiconductor device according to claim 1, wherein the conductive pillar comprises polysilicon.

6. The semiconductor device according to claim 1, wherein the semiconductor device includes a vertical or planar access transistor coupled to the first or second plate of the capacitor.

7. The semiconductor device according to claim 6, wherein the semiconductor device comprises a memory device, wherein the capacitor is adapted to store information.

8. The semiconductor device according to claim 1, wherein the sidewalls and bottom of the at least one trench are doped with a dopant.

9. The semiconductor device according to claim 1, wherein the first conductive material is recessed below a top surface of the pillar.

10. The semiconductor device according to claim 1, further comprising:
a buried strap coupled to the first conductive material; and
a trench top oxide disposed over the pillar and buried strap.

11. A capacitor, comprising:
a substrate;
at least one trench formed in the substrate, the at least one trench having a bottom surface and sidewalls, the at least one trench comprising a lower portion;
a conductive pillar formed in the trench lower portion, the pillar being disposed over and electrically connected to the bottom surface of the at least one trench, wherein the substrate in the lower portion of the at least one trench and the conductive pillar comprise a first plate of the capacitor;
a capacitor dielectric disposed over at least the pillar and the sidewalls of the trench lower portion; and
a conductive material disposed over the dielectric material, the conductive material being recessed below a top surface of the pillar, wherein the conductive material comprises a second plate of the capacitor.

12. The capacitor according to claim 11, wherein at least a top portion of the conductive pillar is hollow.

13. The capacitor according to claim 12, wherein the at least one trench comprises a bottle shape at the lower portion.

14. The capacitor according to claim 11, wherein the conductive material and conductive pillar comprise polysilicon.

15. The capacitor according to claim 11, further comprising a vertical or planar access transistor coupled to the first or second plate of the capacitor.

16. The capacitor according to claim 11, wherein the capacitor is adapted to store data.

17. The capacitor according to claim 11, wherein the sidewalls and bottom of the at least one trench are doped with a dopant.

18. A method of manufacturing a semiconductor device, the method comprising:
providing a substrate;
forming at least one trench in the substrate, the at least one trench comprising a bottom surface and sidewalls, the at least one trench comprising a lower portion and an upper portion;
forming a conductive pillar in the trench lower portion, wherein the pillar is electrically connected to the bottom surface of the at least one trench;
depositing a dielectric over at least the pillar and trench sidewalls; and
depositing a first conductive material over the dielectric.

19. The method according to claim 18, wherein the substrate and pillar comprise a first plate of a capacitor, the dielectric comprises a dielectric of the capacitor, and the first conductive material comprises a second plate of the capacitor.

20. The method according to claim 19, further comprising recessing the first conductive material below a top surface of the pillar.

21. The method according to claim 20, further comprising:
forming an insulating collar in the upper portion of the at least one trench on the trench sidewalls and on sidewalls of the pillar;
depositing a second conductive material over the insulating collar, pillar, and first conductive material;
recessing the second conductive material;
removing exposed portions of the insulating collar; and
forming a trench top oxide over the second conductive material.

22. The method according to claim 21, further comprising forming an access transistor proximate the capacitor.

23. The method according to claim 22, wherein forming the access transistor comprises forming a planar or vertical transistor.

24. The method according to claim 18, wherein forming the conductive pillar comprises:
depositing a masking material over the sidewalls of the at least one trench;
depositing a second conductive material in the lower portion of the at least one trench;
recessing the second conductive material; and
removing the masking material.

25. The method according to claim 24, wherein depositing the second conductive material in the lower portion of the at least one trench comprises forming a void in the second conductive material.

26. The method according to claim 25, further comprising removing a top portion of the second conductive material from the lower portion of the at least one trench.

27. The method according to claim 26, wherein the void in the second conductive material comprises an inner surface, wherein removing the top portion of the second conductive material comprises exposing the inner surface of the void.

28. The method according to claim 27, wherein a top portion of the pillar of second conductive material comprises a hollow portion defined by the inner surface of the void.

29. The method according to claim 27, wherein removing a top portion of the second conductive material comprises an isotropic etch until the void is reached, followed by an anisotropic etch to preferentially etch the second conductive material in a vertical direction within the at least one trench.

30. The method according to claim 29, further comprising:
depositing a thin liner over at least the inner surface of the void, after removing the top portion of the second conductive material; and
removing the thin liner, before depositing the dielectric over at least the pillar and trench sidewalls.

31. The method according to claim 30, wherein the thin liner comprises an oxide or a polymer.
